(19) United States
(12) Patent Application Publication
(10) Pub. No.: US 2023/0145779 A1
(43) Pub. Date: May 11, 2023

(54) Cooling Device

(71) Applicant: Marelli Corporation, Saitama-city, Saitama (JP)

(72) Inventors: Mitsuru Iwasaki, Saitama-city, Saitama (JP); Eiki Hayashi, Saitama-shi, Saitama (JP); Mayumi Yamanaka, Saitama-city, Saitama (JP)

(21) Appl. No.: 17/913,024

(22) PCT Filed: Mar. 30, 2021
(86) PCT No.: PCT/JP2021/013666

§ 371 Date: Sep. 20, 2022

(30) Foreign Application Priority Data
Mar. 31, 2020 (JP) 2020-063569

(51) Int. Cl. H01L 23/473; H05K 7/20

(52) U.S. Cl. CPC H01L 23/473; H05K 7/20218

(57) ABSTRACT

A cooling device has a flat flow path formed between a first wide surface and a second wide surface, the second wide surface including protrusion portions protruding into the flow path, extending in a flow path width direction, and arranged side by side in a fluid flow direction. The first wide surface has no protrusion portions. The protrusion portions each include a first inclined surface inclined to come close to the first wide surface from upstream to downstream in the fluid flow direction, and a second inclined surface disposed alternately with the first inclined surface in the fluid flow direction and inclined to be distanced from the first wide surface from upstream to downstream in the fluid flow direction. The protrusion portions are formed such that a virtual first circle is inscribed at three points on the first wide surface, the second inclined surface, and the first inclined surface.

### CROSS REFERENCE TO RELATED APPLICATION

This application claims priority to Japanese Patent Application No. 2020-063569 filed on Mar. 31, 2020, the entire contents of which is incorporated herein by reference.

### TECHNICAL FIELD

The present invention relates to a cooling device for cooling a device to be cooled.

### BACKGROUND

JP 2020-014278 A discloses an inverter module including a flow path for cooling water (a cooling device) formed between a power module and a capacitor body.

### SUMMARY

However, in the cooling device of JP 2020-014278 A, a heat exchange area with the cooling water is increased by forming fins on a lower surface of the power module, but no study has been made on how the cooling water flows in the flow path.

An object of the present invention is to improve heat exchange efficiency between a device to be cooled and a fluid depending on how the fluid flows through a flow path.

According to an aspect of the present invention, a cooling device that has a first wide surface and a second wide surface facing the first wide surface, and cools a device to be cooled with a fluid flowing through a flat flow path formed between the first wide surface and the second wide surface, wherein the second wide surface has a plurality of protrusion portions protruding into the flow path, the protrusion portions extending in a flow path width direction, the protrusion portions being arranged side by side in a fluid flow direction, the first wide surface is not provided with the protrusion portions, the protrusion portions each include: a first inclined surface inclined to come close to the first wide surface from upstream to downstream in the fluid flow direction; and a second inclined surface disposed alternately with the first inclined surface in the fluid flow direction and inclined to be distanced from the first wide surface from upstream to downstream in the fluid flow direction, and the protrusion portions each are formed such that, in a cross section taken along the fluid flow direction, a virtual first circle is inscribed at three points on the first wide surface, the second inclined surface, and the first inclined surface adjacent to the second inclined surface downstream in the fluid flow direction.

According to the above aspect, in a cross section taken along a fluid flow direction, protrusion portions each are formed such that a virtual first circle is inscribed at three points on a first wide surface, a second inclined surface, and a first inclined surface adjacent to and downstream of the second inclined surface in the fluid flow direction. Therefore, when a fluid flows from the first inclined surface to the second inclined surface adjacent to and downstream of the first inclined surface in the fluid flow direction, a longitudinal vortex is generated and flows along the second inclined surface, and a large longitudinal vortex is generated in a space in which the virtual first circle is inscribed at the three points. Therefore, it is possible to improve heat exchange efficiency between a device to be cooled and the fluid in the space in which the virtual first circle is inscribed at the three points. Therefore, the heat exchange efficiency between the device to be cooled and the fluid can be improved depending on how the fluid flows through a flow path.

### BRIEF DESCRIPTION OF DRAWINGS

FIG. 1 is a perspective view of a cooling device according to an embodiment of the present invention as viewed from above;

FIG. 2 is an exploded perspective view of the cooling device as viewed from below;

FIG. 3 is a cross-sectional view taken along a line III-III in FIG. 2, and is a cross-sectional view of protrusion portions of the cooling device taken along a cooling water flow direction;

FIG. 4 is a bottom view showing a part of a second wide surface of the cooling device;

FIG. 5 is a cross-sectional view of the cooling device taken along a fluid flow direction and shows only a part of the cooling device in the fluid flow direction;

FIG. 6 is a bottom view schematically showing flow of a fluid in the protrusion portion;

FIG. 7 is a cross-sectional view of a side surface schematically showing the flow of the fluid in the protrusion portion;

FIG. 8 is a graph showing a ratio of a heat transfer coefficient with respect to Rm1×P/Dv, where Rm1 is a radius of a first circle C1, P is a pitch between peak portions adjacent to each other in the fluid flow direction, and Dv is a distance between a peak portion and a first wide surface;

FIG. 9 shows a value of Rm1×P/Dv for each shape when an inclination angle θt, the pitch P, the distance Dv, and the radius Rm1 are changed;

FIG. 10 is a graph showing upper and lower limit values of the inclination angle θt and an upper limit value of the distance Dv;

FIG. 11 is a graph showing a relation between the inclination angle θt and resistance ΔP;

FIG. 12 is a graph showing a relation between the pitch P and the heat transfer coefficient;

FIG. 13 is a graph showing a relation between the pitch P and the resistance ΔP;

FIG. 14 is a graph showing a ratio of a heat transfer coefficient with respect to Rm1×P/Dv for a fluid having different Reynolds numbers;

FIG. 15 is a perspective view illustrating a flow path according to a first modification of the embodiment of the present invention;

FIG. 16 is a bottom view illustrating flow of a fluid in the first modification shown in FIG. 15;

FIG. 17 is a perspective view illustrating a flow path according to a second modification of the embodiment of the present invention;

FIG. 18 is a perspective view illustrating a flow path according to a third modification of the embodiment of the present invention;

FIG. 19 is a perspective view illustrating a flow path according to a fourth modification of the embodiment of the present invention;

FIG. 20 is a perspective view illustrating a flow path according to a fifth modification of the embodiment of the present invention;

FIG. 21 is a perspective view illustrating a flow path according to a sixth modification of the embodiment of the present invention;

FIG. 22 is a perspective view illustrating a flow path according to a seventh modification of the embodiment of the present invention; and

FIG. 23 is a perspective view illustrating a flow path according to an eighth modification of the embodiment of the present invention.

### DETAILED DESCRIPTION

Hereinafter, a cooling device 1 according to an embodiment of the present invention will be described with reference to the drawings.

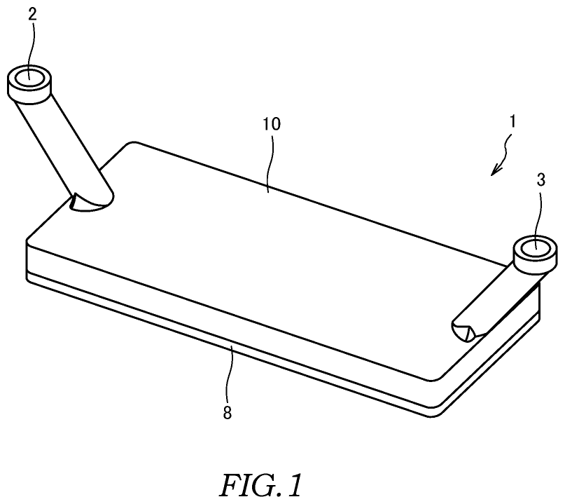

First, an overall configuration of the cooling device 1 will be described with reference to FIGS. 1 to 5.

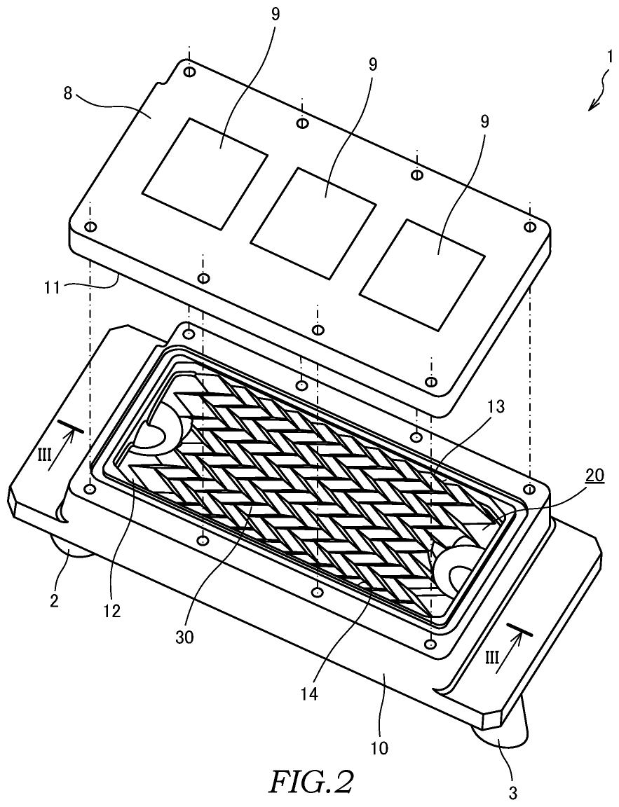

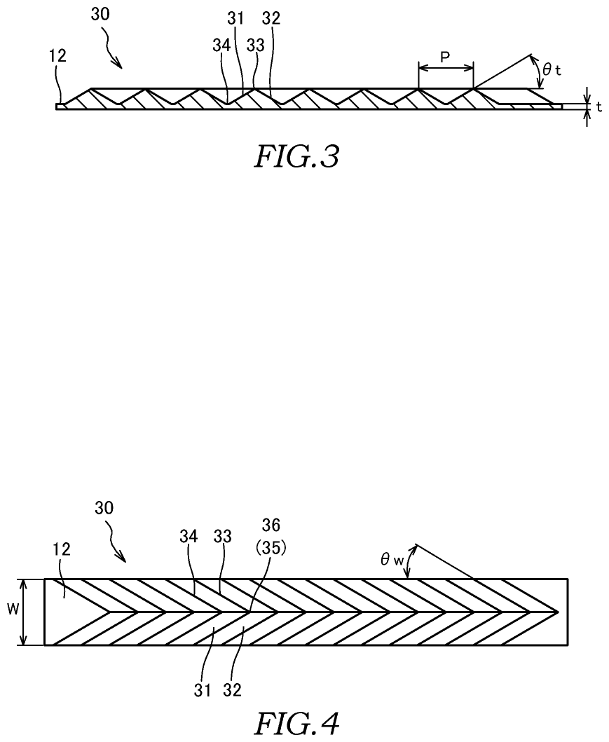

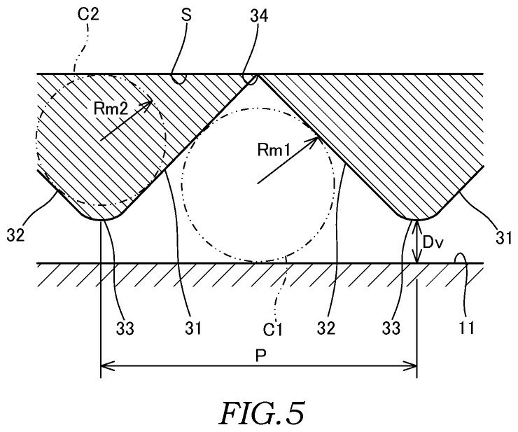

FIG. 1 is a perspective view of the cooling device 1 as viewed from above. FIG. 2 is an exploded perspective view of the cooling device 1 as viewed from below. FIG. 3 is a cross-sectional view taken along a line III-III in FIG. 2, and is a cross-sectional view of protrusion portions 30 of the cooling device 1 taken along a cooling water flow direction. FIG. 4 is a bottom view showing a part of a second wide surface 12 on which the protrusion portions 30 are formed. FIG. 5 is a cross-sectional view of the cooling device 1 taken along the cooling water flow direction, and shows only a part of the cooling device 1 in the cooling water flow direction.

As shown in FIG. 1, the cooling device 1 includes an inlet flow path 2, an outlet flow path 3, and a main body portion 10 that forms a flow path 20 (see FIG. 2). Here, the cooling device 1 cools an inverter module 8 as a device to be cooled by heat exchange with cooling water as a fluid flowing through the flow path 20.

The inverter module 8 controls, for example, a driving motor (not shown) of a vehicle. As shown in FIG. 2, the inverter module 8 includes three switching elements 9 along a flow direction of the cooling water in the flow path 20. The inverter module 8 converts direct current power and alternating current power to each other by switching ON/OFF of the switching elements 9.

The switching elements 9 corresponds to a U phase, a V phase, and a W phase of the inverter module 8, respectively. The switching elements 9 are switched between ON and OFF at high speed to generate heat. The switching elements 9 that have generated the heat are cooled by exchanging heat with the cooling water in the flow path 20.

As shown in FIG. 1, the inlet flow path 2 is a flow path for supplying the cooling water to the flat flow path 20 (see FIG. 2) formed in the main body portion 10. The inlet flow path 2 is provided to protrude from the main body portion 10. The inlet flow path 2 is formed to be inclined with respect to the main body portion 10 so as to supply the cooling water along the cooling water flow direction in the flow path 20.

The outlet flow path 3 is a flow path for draining the cooling water from the flow path 20. The outlet flow path 3 is provided to protrude from the main body portion 10. The outlet flow path 3 is formed to be inclined with respect to the main body portion 10 so as to guide the drained cooling water along the cooling water flow direction in the flow path 20.

As shown in FIG. 2, the main body portion 10 includes the second wide surface 12, a first side surface 13, and a second side surface 14. The inverter module 8 has a first wide surface 11. The flow path 20 is formed flat by the first wide surface 11, the second wide surface 12, the first side surface 13, and the second side surface 14.

In the present embodiment, the first wide surface 11 is formed by a bottom surface of the inverter module 8. That is, the cooling device 1 includes the main body portion 10 and the inverter module 8. In this case, the heat exchange efficiency can be improved by bringing the cooling water into direct contact with the inverter module 8.

Alternatively, the main body portion 10 may be formed to have the first wide surface 11, and the inverter module 8 may be brought into contact with the outside of the first wide surface 11. In this case, the cooling device 1 includes only the main body portion 10.

Here, a direction in which the cooling water flows through the flow path 20 is referred to as the “cooling water flow direction” (a fluid flow direction), a direction perpendicular to the cooling water flow direction and parallel to the first wide surface 11 and the second wide surface 12 is referred to as a “flow path width direction”, and a direction perpendicular to the cooling water flow direction and parallel to the first side surface 13 and the second side surface 14 is referred to as a “flow path height direction”. The “cooling water flow direction” is not a local flow direction of the cooling water in which a traveling direction has changed due to an influence of the protrusion portions 30, but is a flow direction of the cooling water when the flow path 20 as a whole is viewed.

The first wide surface 11 is formed in a planar shape extending linearly in the cooling water flow direction and also extending linearly in the flow path width direction orthogonal to the cooling water flow direction. The first wide surface 11 cools the inverter module 8 with the cooling water flowing through the flow path 20. The first wide surface 11 is not provided with the protrusion portions 30 to be described later.

The second wide surface 12 faces the first wide surface 11 in the flow path height direction with a space corresponding to a flow path height. Accordingly, the flat flow path 20 is formed between the first wide surface 11 and the second wide surface 12. Here, a flow path height of a narrowest portion of the flow path 20, that is, a distance Dv (see FIG. 5) between a peak portion 33 to be described later and the first wide surface 11 is 0.1 to 10 [mm]. The second wide surface 12 has the protrusion portions 30 protruding into the flow path 20 and extending in the flow path width direction.

A plurality of protrusion portions 30 are arranged side by side in parallel with the cooling water flow direction. The protrusion portions 30 are formed over an entire width of the flow path 20 in the flow path width direction. When there is a portion where the protrusion portions 30 are not formed, the cooling water may bypass the portion, but the protrusion portions 30 are formed over the entire width in the flow path width direction, and thus it is possible to prevent a decrease in heat exchange efficiency.

As shown in FIG. 3, the protrusion portions 30 each include a first inclined surface 31, a second inclined surface 32, the peak portion 33, and a valley portion 34.

The first inclined surface 31 is inclined to come close to the first wide surface 11 from upstream to downstream in the cooling water flow direction. The first inclined surface 31 is formed in a planar shape. The first inclined surface 31 is inclined at an inclination angle θt with respect to the second wide surface 12. The inclination angle θt is preferably 15[°] to 45 [°], and is 30 [°] here. A thickness t of the second wide surface 12 is 1 [mm].

The second inclined surface 32 is alternately arranged with the first inclined surface 31 in the cooling water flow direction, and is inclined to be distanced from the first wide surface 11 from upstream to downstream in the cooling water flow direction. The second inclined surface 32 is formed in a planar shape. Similarly, the second inclined surface 32 is inclined at the inclination angle θt with respect to the second wide surface 12.

The peak portion 33 is formed between the first inclined surface 31 and the second inclined surface 32 adjacent to and downstream of the first inclined surface 31 in the cooling water flow direction. Here, a pitch P between adjacent peak portions 33 is 11 [mm]. The peak portion 33 is formed at a top portion where the first inclined surface 31 and the second inclined surface 32 abut each other. Alternatively, the peak portion 33 may be formed by a curved surface that gently connects the first inclined surface 31 and the second inclined surface 32, or the peak portion 33 may be formed by a flat surface that connects the first inclined surface 31 and the second inclined surface 32.

The valley portion 34 is formed between the second inclined surface 32 and the first inclined surface 31 adjacent to and downstream of the second inclined surface 32 in the cooling water flow direction. The valley portion 34 is formed in a bottom portion where the second inclined surface 32 and the first inclined surface 31 abut each other. Alternatively, the valley portion 34 may be formed by a curved surface that gently connects the second inclined surface 32 and the first inclined surface 31, or the valley portion 34 may be formed by a flat surface that connects the second inclined surface 32 and the first inclined surface 31.

When the cooling water passes through the flow path 20 between the peak portion 33 and the first wide surface 11, the cooling water tends to flow in a direction nearly perpendicular to a ridge line of the peak portion 33 so as to reduce resistance. On the other hand, when the cooling water passes through the flow path 20 between the valley portion 34 and the first wide surface 11, the cooling water tends to flow in a direction along a ridge line of the valley portion 34 having low resistance. In this way, the cooling water alternately passes through the peak portion 33 and the valley portion 34, and thus a strong swirling flow (a longitudinal vortex) is generated in the valley portion 34 sandwiched between a pair of peak portions 33. Therefore, the longitudinal vortex can be efficiently generated.

As shown in FIG. 4, the protrusion portions 30 adjacent to each other in the flow path width direction are inclined in opposite directions so as to alternate in the cooling water flow direction. An inclination angle θw of each of the protrusion portions 30 in the flow path width direction with respect to the cooling water flow direction is preferably 15 [°] to 40 [°], and is 30 [°] here.

Although FIG. 4 shows only a pair of protrusion portions 30 adjacent to each other in the flow path width direction, the protrusion portions 30 are further provided side by side in the flow path width direction. That is, the protrusion portions 30 adjacent to each other in the flow path width direction are formed so that a V shape is continuous in the flow path width direction. Here, a size W in the flow path width direction of the pair of protrusion portions 30 adjacent to each other in the flow path width direction is 12.7 [mm].

Ridge lines of the peak portions 33 adjacent to each other in the flow path width direction are continuously formed. Ridge lines of the valley portions 34 adjacent to each other in the flow path width direction are formed continuously. Accordingly, it is possible to improve a temperature distribution of the cooling water in the flow path 20. The protrusion portions 30 have a connection portion 35 formed between the peak portions 33 that are continuous in the flow path width direction, and a top portion 36 of the connection portion 35 that protrudes downstream in the cooling water flow direction.

As shown in FIG. 5, the protrusion portions 30 each are formed such that, in a cross section taken along the cooling water flow direction, a virtual first circle C1 is inscribed at three points on the first wide surface 11, the second inclined surface 32, and the first inclined surface 31 adjacent to and downstream of the second inclined surface 32 in the cooling water flow direction. Further, the protrusion portion 30 is formed such that the valley portion 34 does not fall within the first circle C1.

Similarly, the protrusion portions 30 each are formed such that, in a cross section taken along the cooling water flow direction, a virtual second circle C2 is inscribed at three points on the first inclined surface 31 upstream of the peak portion 33, the second inclined surface 32 downstream of the peak portion 33, and a virtual facing surface S facing the first wide surface 11 and in which the valley portion 34 is located. Further, the protrusion portion 30 is formed such that the peak portion 33 does not fall within the second circle C2. Accordingly, the heat exchange efficiency can be improved without unnecessary increase in resistance.

Here, as shown in FIG. 5, a radius of the first circle C1 is denoted by Rm1, a radius of the second circle C2 is denoted by Rm2, a pitch between the peak portions 33 adjacent to each other in the cooling water flow direction is denoted by P, and a distance between the peak portion 33 and the first wide surface 11 is denoted by Dv. A shape of the protrusion portion 30 is determined when the radius Rm1 of the first circle C1, the pitch P between the peak portions 33, and the distance Dv are known.

At this time, sizes of the first circle C1 and the second circle C2 have a relation of Rm1>Rm2.

In this way, by setting Rm1>Rm2, it is possible to sufficiently secure a flow path cross-sectional area of the flow path 20 between the peak portion 33 and the first wide surface 11.

Next, an operation of the cooling device 1 will be described with reference to FIGS. 5 to 14.

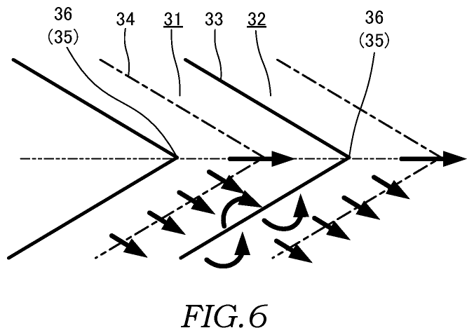

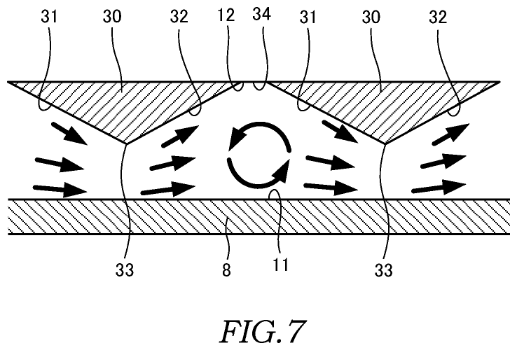

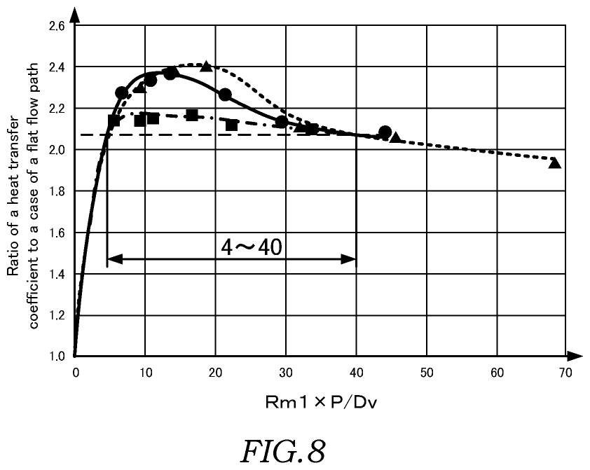

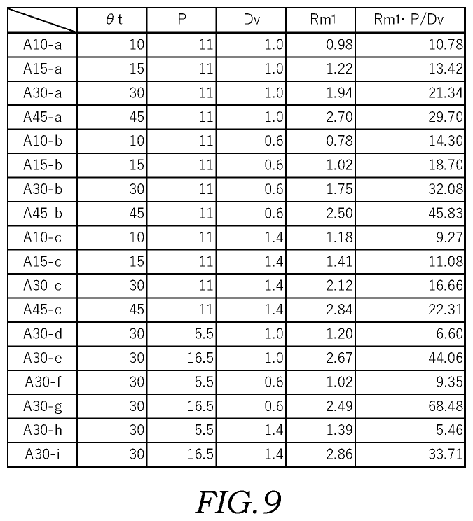

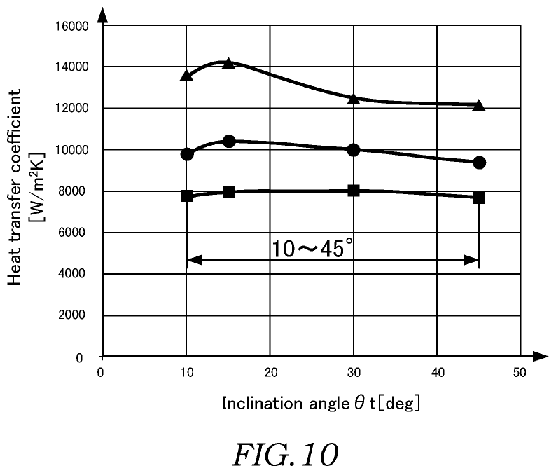

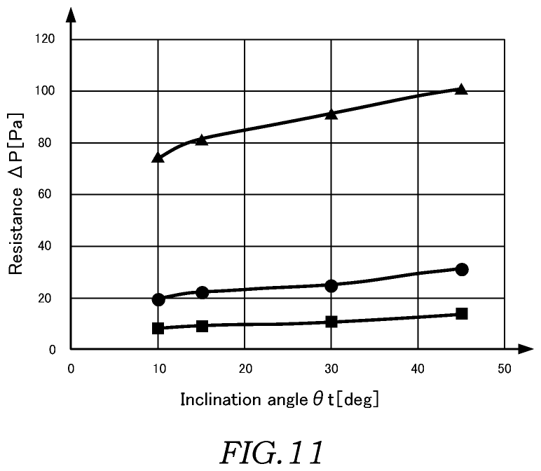

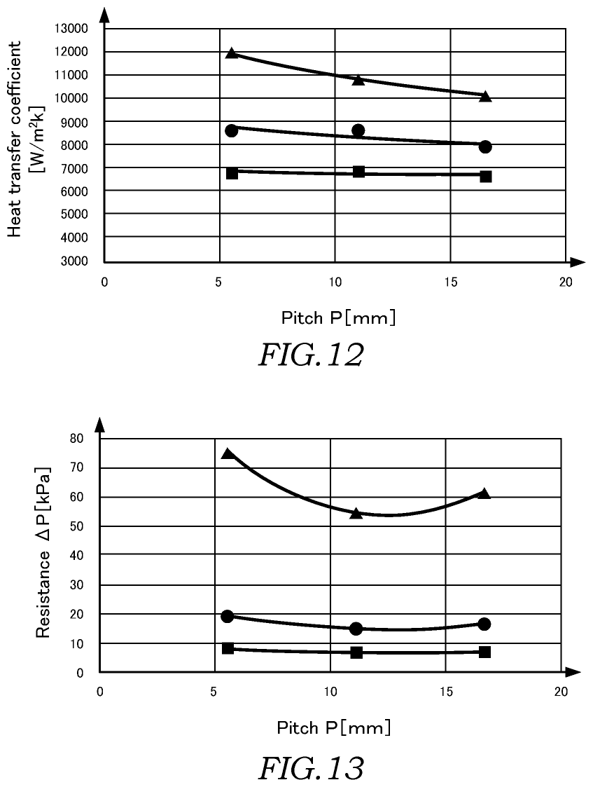

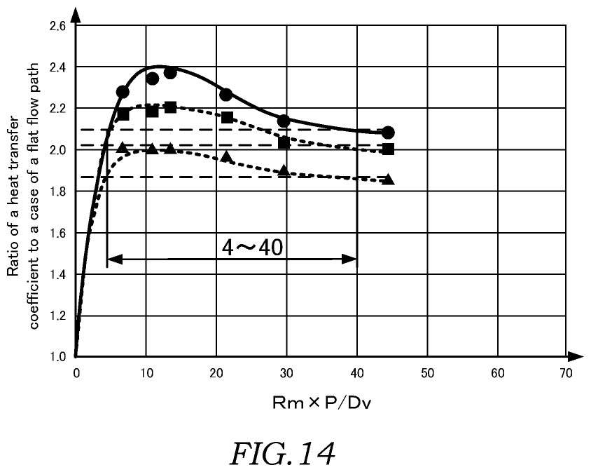

FIG. 6 is a plan view schematically showing flow of the cooling water in the protrusion portions 30. FIG. 7 is a cross-sectional view of a side surface schematically showing the flow of the cooling water in the protrusion portion 30. FIG. 8 is a graph showing a ratio of a heat transfer coefficient with respect to Rm1×P/Dv, where Rm1 is the radius of the first circle C1, P is the pitch between the peak portions 33 adjacent to each other in the cooling water flow direction, and Dv is the distance between the peak portion 33 and the first wide surface 11. FIG. 9 shows a value of Rm1×P/Dv for each shape when the inclination angle θt, the pitch P, the distance Dv, and the radius Rm1 are changed. FIG. 10 is a graph showing upper and lower limit values of the inclination angle θt and an upper limit value of the distance Dv. FIG. 11 is a graph showing a relation between the inclination angle θt and resistance ΔP [Pa]. FIG. 12 is a graph showing a relation between the pitch P and the heat transfer coefficient. FIG. 13 is a graph showing a relation between the pitch P and the resistance ΔP. FIG. 14 is a graph showing a ratio of a heat transfer coefficient with respect to Rm1×P/Dv for a fluid having different Reynolds numbers Re.

As shown in FIGS. 6 and 7, when the cooling water flows from the first inclined surface 31 to the second inclined surface 32 adjacent to and downstream of the first inclined surface 31 in the cooling water flow direction, the longitudinal vortex is generated and flows along the second inclined surface 32. Then, a large longitudinal vortex is formed in a space (see FIG. 5) in which the virtual first circle C1 is inscribed at the three points. Therefore, it is possible to improve heat exchange efficiency between the inverter module 8 and the cooling water in the space in which the virtual first circle C1 is inscribed at the three points. Therefore, the heat exchange efficiency between the inverter module 8 and the cooling water can be improved depending on how the cooling water flows through the flow path 20.

A horizontal axis of FIG. 8 is Rm1×P/Dv (Rm1 is the radius of the first circle C1, P is the pitch between the peak portions 33 (or between the valley portions 34), and Dv is the distance between the peak portion 33 and the first wide surface 11). A vertical axis of FIG. 8 is a ratio of a heat transfer coefficient to a case of a flat flow path in which the protrusion portions 30 are not formed.

Here, in the cooling device 1, while the swirling flow is generated toward the valley portion 34, the swirling flow is contracted between the peak portion 33 and the first wide surface 11 (a portion of the distance Dv), and thus a temperature boundary layer is thinned and the heat exchange efficiency is improved. The radius Rm1, the pitch P, and the distance Dv are parameters that are related to each other in order to generate a series of flows. Specifically, the radius Rm1 has an inverse correlation in which the ratio is relatively large as the distance Dv is small, and the pitch P has an inverse correlation in which the ratio is relatively large as the distance Dv is small. In this way, there is a geometric correlation among the radius Rm1, the pitch P, and the distance Dv. Therefore, since the geometric correlation affects the flow, a peak can be indicated by a value of Rm1×P/Dv.

FIG. 8 shows, as an example, a case where Re=1640 in a range of the Reynolds number Re that is frequently used in the cooling device 1. Each plot in FIG. 8 shows a case of each shape shown in FIG. 9. In FIG. 8, a plot of a triangle (▴) is a case where the distance Dv is 0.6 [mm], a plot of a circle (●) is a case where the distance Dv is 1.0 [mm], and a plot of a square (▪) is a case where the distance Dv is 1.4 [mm].

Referring to FIG. 8, when the distance Dv is 1.0 [mm], a value of an inflection point, that is, when Rm1×P/Dv is 40, is set as an upper limit, and a lower limit value is set to 4 based on the ratio of the heat transfer coefficient to the case of the flat flow path at that time. Therefore, it can be seen that performance of the cooling device 1 is improved when Rm1×P/Dv is in a range of 4 to 40. Therefore, by setting Rm1×P/Dv in the range of 4 to 40, the heat transfer coefficient can be improved, that is, a performance improvement margin can be increased. It can be seen that the performance of the cooling device 1 is similarly improved when the distance Dv is in a range of 0.6 to 1.4 [mm] based on the case where the distance Dv is 1.0 [mm].

Subsequently, upper and lower limit values of each parameter in Rm1×P/Dv will be described with reference to FIGS. 10 to 14.

In FIG. 10, a horizontal axis represents the inclination angle θt, and a vertical axis represents the heat transfer coefficient [W/m²K]. In FIG. 10, a plot of a triangle (▴) is a case where the distance Dv is 0.6 [mm], a plot of a circle (●) is a case where the distance Dv is 1.0 [mm], and a plot of a square (▪) is a case where the distance Dv is 1.4 [mm].

As shown in FIG. 10, when the distance Dv is 1.4 [mm], a change in a magnitude of the heat transfer coefficient in a range of the inclination angle θt of 10° to 45° is less than 5%. Therefore, based on FIG. 10, the upper limit value of the distance Dv is 1.4 [mm], a lower limit value of the inclination angle θt is 10 [°], and an upper limit value of the inclination angle θt is 45 [°].

In FIG. 11, a horizontal axis represents the inclination angle θt, and a vertical axis represents the resistance ΔP [Pa]. In FIG. 11, a plot of a triangle (▴) is a case where the distance Dv is 0.6 [mm], a plot of a circle (●) is a case where the distance Dv is 1.0 [mm], and a plot of a square (▪) is a case where the distance Dv is 1.4 [mm].

As shown in FIG. 11, when the distance Dv is 0.6 [mm], the resistance ΔP is five times or more the resistance ΔP when the distance Dv is 1.4 [mm]. Therefore, the lower limit value of the distance Dv is 0.6 [mm].

In FIG. 12, a horizontal axis represents the pitch P [mm], and the vertical axis represents the heat transfer coefficient [W/m²K]. In FIG. 13, a horizontal axis represents the pitch P [mm], and a vertical axis represents the resistance ΔP [kPa]. In FIGS. 12 and 13, a plot of a triangle (▴) is a case where the distance Dv is 0.6 [mm], a plot of a circle (●) is a case where the distance Dv is 1.0 [mm], and a plot of a square (▪) is a case where the distance Dv is 1.4 [mm].

As shown in FIGS. 12 and 13, when the pitch is 16.5 [mm], the heat transfer coefficient decreases and the resistance ΔP increases. Therefore, the upper limit value of the pitch P is 16.5 [mm]. On the other hand, when the pitch P is 5.5 [mm], an increase in heat transfer coefficient from the pitch P of 11.0 [mm] is 10%, while the resistance ΔP is increased by 37%. It can be expected that the resistance ΔP increases quadratically when the pitch P is smaller than 5.5 [mm]. Therefore, the lower limit value of the pitch P is 5.5 [mm].

A size of the radius Rm1 is determined by the inclination angle θt, the distance Dv, and the pitch P. Thus, a range of the size of the radius Rm1 can be obtained as follows based on upper and lower limit values of the inclination angle θt, the distance Dv, and the pitch P. A lower limit value of the radius Rm1 is a value when the inclination angle θt is 10 [° ], the distance Dv is 0.6 [mm], and the pitch P is 5.5 [mm], and is 0.54 [mm] here. An upper limit value of the radius Rm1 is a value when the inclination angle θtis 45 [°], the distance Dv is 1.4 [mm], and the pitch P is 16.5 [mm], and is 3.61 [mm] here.

FIG. 14 adds a case where the Reynolds numbers Re of the fluid are different when the distance Dv is 1.0 [mm] in the graph of FIG. 8. In FIG. 14, a plot of a circle (●) is a case where the Reynolds number Re of the fluid is 1640, a plot of a square (▪) is a case where the Reynolds number Re of the fluid is 1230, and a plot of a triangle (▴) is a case where the Reynolds number Re of the fluid is 820.

As shown in FIG. 14, when the Reynolds number Re of the fluid is small, a peak of a peak value is low and gentle, and is offset to a lower side. However, it can be seen that even if the Reynolds number Re of the fluid is changed, an overall tendency is the same.

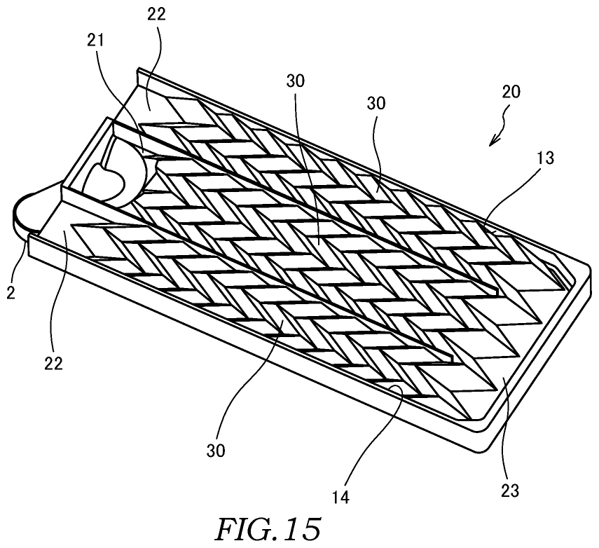

Hereinafter, first to eighth modifications of the embodiment of the present invention will be described with reference to FIGS. 15 to 23.

First, a first modification and a second modification of the embodiment of the present invention will be described with reference to FIGS. 15 to 17.

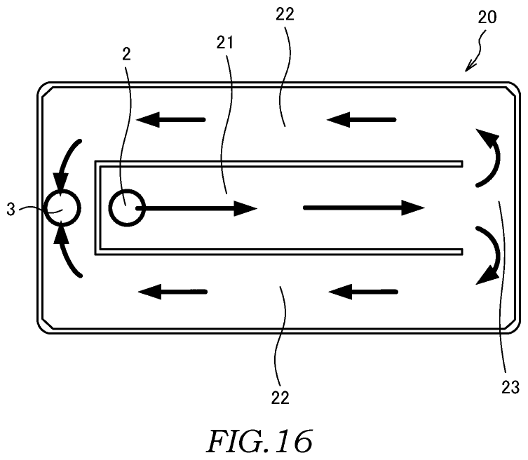

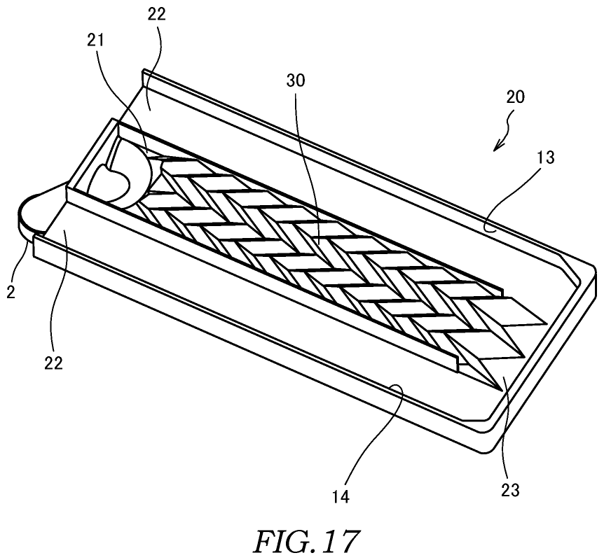

FIG. 15 is a perspective view illustrating the flow path 20 according to the first modification of the embodiment of the present invention. FIG. 16 is a plan view illustrating flow of cooling water in the first modification shown in FIG. 15. FIG. 17 is a perspective view illustrating the flow path 20 according to the second modification of the embodiment of the present invention.

As shown in FIG. 15, the flow path 20 includes a central flow path 21, a side flow path 22, and a turn flow path 23.

The central flow path 21 is formed at a position in a flow path width direction corresponding to a central portion of the inverter module 8 having a large heat generation amount. The central flow path 21 is provided with the protrusion portions 30. Therefore, the central portion of the inverter module 8 can be preferentially cooled by cooling water flowing through the central flow path 21.

The side flow path 22 is provided outside the central flow path 21 in the flow path width direction. The side flow path 22 is provided with the protrusion portions 30. Therefore, a portion of the inverter module 8 having a relatively small heat generation amount can be further cooled by the cooling water whose temperature has risen due to heat exchange with the inverter module 8 in the central flow path 21.

The turn flow path 23 turns the cooling water back from the central flow path 21 toward the side flow path 22. As shown in FIG. 16, the cooling water turned back in the turn flow path 23 passes through the side flow path 22 and is drained from the outlet flow path 3.

As described above, since the central portion of the inverter module 8 in the flow path width direction has a large heat generation amount, the inverter module 8 can be efficiently cooled by providing the protrusion portions 30 in the central flow path 21 that cools the central portion. The cooling water turned back via the turn flow path 23 flows through the side flow path 22, and thus it is possible to further cool the portion of the inverter module 8 having a relatively small heat generation amount.

Since the protrusion portions 30 are formed not only in the central flow path 21 but also in the side flow path 22, the heat exchange efficiency of the inverter module 8 can be further improved.

As in the second modification shown in FIG. 17, the protrusion portions 30 may not be formed in the side flow path 22 depending on the heat generation amount of the inverter module 8. In this case, resistance of the cooling water can be reduced by not forming the protrusion portions 30 in the side flow path 22.

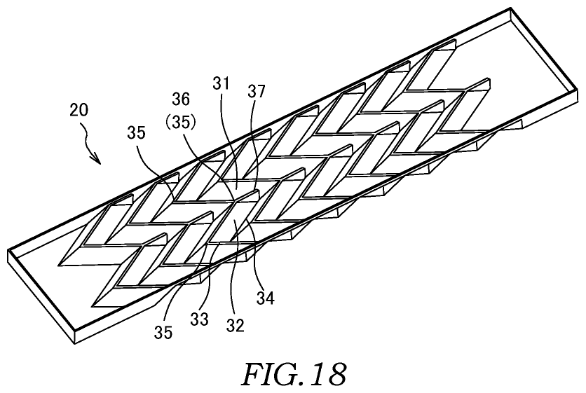

Next, a third modification of the embodiment of the present invention will be described with reference to FIG. 18.

FIG. 18 is a perspective view illustrating the flow path 20 according to the third modification of the embodiment of the present invention.

As shown in FIG. 18, the protrusion portion 30 each further includes a rectifying fin 37 extending downstream in the cooling water flow direction from the top portion 36 protruding downstream in the cooling water flow direction in the connection portion 35 between the peak portions 33 continuous in the flow path width direction.

The rectifying fin 37 is formed downstream in the cooling water flow direction from the peak portion 33. The rectifying fin 37 is formed to have a length to the valley portion 34 along the second inclined surface 32.

In this way, since the flow path 20 is partitioned in the flow path width direction by providing the rectifying fin 37, it is possible to prevent interference between longitudinal vortices of the cooling water on both sides of the rectifying fin 37. Therefore, it is possible to improve cooling performance while preventing an increase in resistance of the cooling water.

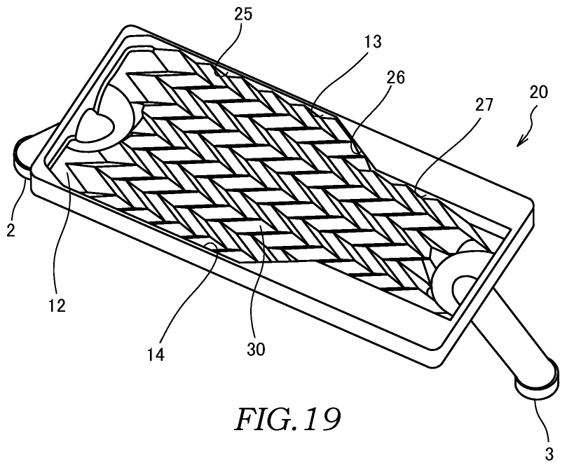

Next, a fourth modification of the embodiment of the present invention will be described with reference to FIG. 19.

FIG. 19 is a perspective view illustrating the flow path 20 according to the fourth modification of the embodiment of the present invention.

As shown in FIG. 19, the flow path 20 includes a wide portion 25, a width reducing portion 26, and a narrow portion 27. The flow path 20 is formed such that a downstream side in the cooling water flow direction is narrower in the flow path width direction than an upstream side in the cooling water flow direction.

The wide portion 25 is formed such that the cooling water cools the entire inverter module 8 in the flow path width direction. The wide portion 25 is formed at a portion into which the cooling water flows from the inlet flow path 2. Therefore, the cooling water having a relatively low temperature flows through the wide portion 25. Therefore, the wide portion 25 is formed, and thus it is possible to widely cool the inverter module 8 while preventing a flow velocity of the cooling water.

The width reducing portion 26 gradually reduces a flow path width from the wide portion 25 toward the narrow portion 27. The width reducing portion 26 is formed along the ridge line of the valley portion 34. Therefore, the flow path width can be reduced so as not to hinder the flow of the longitudinal vortex formed by the protrusion portions 30, and thus an increase in resistance can be prevented.

The narrow portion 27 is formed to be narrower than the wide portion 25 in the flow path width direction. The narrow portion 27 is formed at a position in the flow path width direction corresponding to the central portion of the inverter module 8 having a large heat generation amount. The cooling water flowing through the narrow portion 27 has a higher flow velocity than the cooling water flowing through the wide portion 25. Therefore, even when the inverter module 8 is cooled at the wide portion 25 and the width reducing portion 26 and the temperature of the cooling water is increased, the inverter module 8 can be cooled at the narrow portion 27 by increasing the flow velocity.

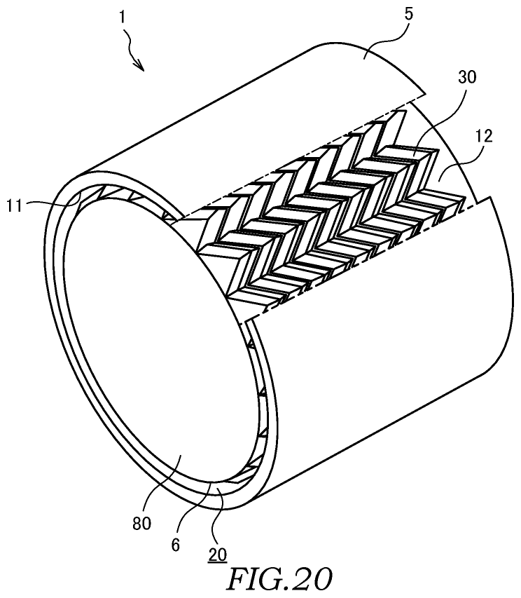

Next, fifth to eighth modifications of the embodiment of the present invention will be described with reference to FIGS. 20 to 23.

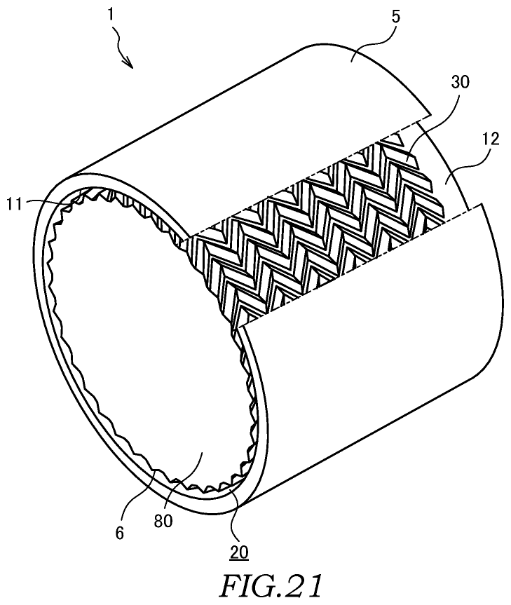

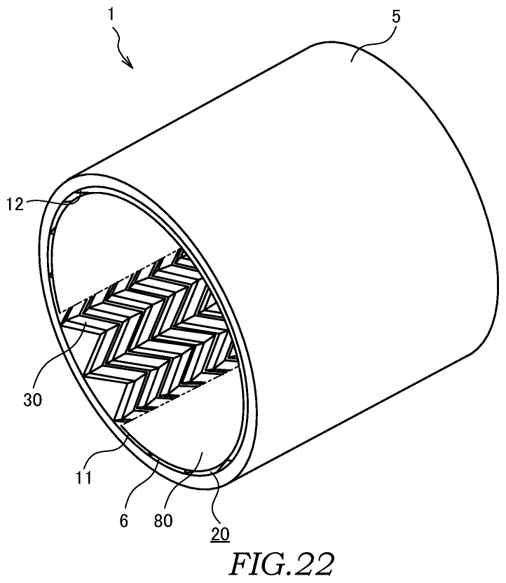

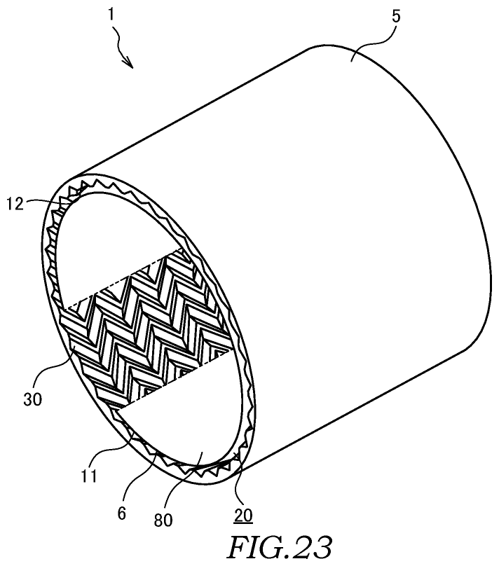

FIG. 20 is a perspective view illustrating the flow path 20 according to a fifth modification of the embodiment of the present invention. FIG. 21 is a perspective view illustrating the flow path 20 according to a sixth modification of the embodiment of the present invention. FIG. 22 is a perspective view illustrating the flow path 20 according to a seventh modification of the embodiment of the present invention. FIG. 23 is a perspective view illustrating the flow path 20 according to an eighth modification of the embodiment of the present invention.

FIGS. 20 to 23 show a state in which a part of an outer cylinder 5 or an inner cylinder 6 is cut off so that a shape of the protrusion portion 30 can be seen. In each of the modifications shown in FIGS. 20 to 23, an electric motor (driving motor) 80 having a cylindrical outer shape is applied as the device to be cooled instead of the inverter module 8.

In the fifth modification shown in FIG. 20, the cooling device 1 includes a tubular outer cylinder 5 and a tubular inner cylinder 6 that is provided at an interval on an inner periphery of the outer cylinder 5 and accommodates the electric motor 80 on the inner periphery. An inner diameter of the outer cylinder 5 is formed to be larger than an outer diameter of the inner cylinder 6. The first wide surface 11 is formed on the inner periphery of the outer cylinder 5, and the second wide surface 12 is formed on an outer periphery of the inner cylinder 6.

The flow path 20 is formed in an annular shape between the outer cylinder 5 and the inner cylinder 6. The cooling water flows through the flow path 20 in a central axis direction. That is, the first wide surface 11 and the second wide surface 12 linearly extend in the cooling water flow direction, and are circularly curved in a direction orthogonal to the cooling water flow direction.

The protrusion portions 30 protrude from an outer periphery of the second wide surface 12 into the flow path 20 and extend in the flow path width direction, and are arranged side by side in the central axis direction of the flow path 20, which is the cooling water flow direction. The protrusion portions 30 are not provided on the first wide surface 11.

In the sixth modification shown in FIG. 21, the cooling device 1 includes a tubular outer cylinder 5 and a tubular inner cylinder 6 that is provided at an interval on an inner periphery of the outer cylinder 5 and accommodates the electric motor 80 on the inner periphery. An inner diameter of the outer cylinder 5 is formed to be larger than an outer diameter of the inner cylinder 6. The first wide surface 11 is formed on the inner periphery of the outer cylinder 5, and the second wide surface 12 is formed on an outer periphery of the inner cylinder 6.

The flow path 20 is formed in an annular shape between the outer cylinder 5 and the inner cylinder 6. The cooling water flows through the flow path 20 in a circumferential direction. That is, the first wide surface 11 and the second wide surface 12 are circularly curved in the cooling water flow direction, and linearly extend in a direction orthogonal to the cooling water flow direction.

The protrusion portions 30 protrude from an outer periphery of the second wide surface 12 into the flow path 20 and extend in the flow path width direction, and are arranged side by side in the circumferential direction of the flow path 20, which is the cooling water flow direction. The protrusion portions 30 are not provided on the first wide surface 11.

In the seventh modification shown in FIG. 22, the cooling device 1 includes a tubular outer cylinder 5 and a tubular inner cylinder 6 that is provided at an interval on an inner periphery of the outer cylinder 5 and accommodates the electric motor 80 on the inner periphery. An inner diameter of the outer cylinder 5 is formed to be larger than an outer diameter of the inner cylinder 6. The second wide surface 12 is formed on the inner periphery of the outer cylinder 5, and the first wide surface 11 is formed on an outer periphery of the inner cylinder 6.

The flow path 20 is formed in an annular shape between the outer cylinder 5 and the inner cylinder 6. The cooling water flows through the flow path 20 in a central axis direction. That is, the first wide surface 11 and the second wide surface 12 linearly extend in the cooling water flow direction, and are circularly curved in a direction orthogonal to the cooling water flow direction.

The protrusion portions 30 protrude from an inner periphery of the second wide surface 12 into the flow path 20 and extend in the flow path width direction, and are arranged side by side in the central axis direction of the flow path 20, which is the cooling water flow direction. The protrusion portions 30 are not provided on the first wide surface 11.

In the eighth modification shown in FIG. 23, the cooling device 1 includes a tubular outer cylinder 5 and a tubular inner cylinder 6 that is provided at an interval on an inner periphery of the outer cylinder 5 and accommodates the electric motor 80 on the inner periphery. An inner diameter of the outer cylinder 5 is formed to be larger than an outer diameter of the inner cylinder 6. The second wide surface 12 is formed on the inner periphery of the outer cylinder 5, and the first wide surface 11 is formed on an outer periphery of the inner cylinder 6.

The flow path 20 is formed in an annular shape between the outer cylinder 5 and the inner cylinder 6. The cooling water flows through the flow path 20 in a circumferential direction. That is, the first wide surface 11 and the second wide surface 12 are circularly curved in the cooling water flow direction, and linearly extend in a direction orthogonal to the cooling water flow direction.

The protrusion portions 30 protrude from an inner periphery of the second wide surface 12 into the flow path 20 and extend in the flow path width direction, and are arranged side by side in the circumferential direction of the flow path 20, which is the cooling water flow direction. The protrusion portions 30 are not provided on the first wide surface 11.

As described above, in the fifth to eighth modifications, the first wide surface 11 and the second wide surface 12 extend linearly in one direction of the cooling water flow direction and the direction orthogonal to the cooling water flow direction, and extend linearly or are circularly curved in the other direction. In this way, the flat flow path 20 may be formed not only in a geometric planar shape including two straight lines but also in a curved surface shape. Specifically, the flow path 20 is formed between the outer cylinder 5 and the inner cylinder 6 formed in a tubular shape, and may be circularly curved in the cooling water flow direction or may be circularly curved in the direction orthogonal to the cooling water flow direction.

In this way, not only in a case where the first wide surface 11 and the second wide surface 12 are formed in a planar shape, but also in a case where the flow path 20 is formed in the circumferential direction or in a case where the flow path 20 is circularly curved in the width direction, similarly, by providing the protrusion portions 30, the heat exchange efficiency between the electric motor 80 as the device to be cooled and the cooling water can be improved depending on how the cooling water flows through the flow path 20.

According to the above embodiment, the following effects are exerted.

In a cooling device 1 that has a first wide surface 11 and a second wide surface 12 facing the first wide surface 11, and cools an inverter module 8 with cooling water flowing through a flat flow path 20 formed between the first wide surface 11 and the second wide surface 12, the first wide surface 11 cools the inverter module 8 with the cooling water, the second wide surface 12 has a plurality of protrusion portions 30 protruding into the flow path 20, extending in a flow path width direction, the protrusion portions 30 being arranged side by side in a cooling water flow direction, the first wide surface 11 is not provided with the protrusion portions 30, the protrusion portions 30 each have a first inclined surface 31 inclined to come close to the first wide surface 11 from upstream to downstream in the cooling water flow direction, and a second inclined surface 32 disposed alternately with the first inclined surface 31 in the cooling water flow direction and inclined to be distanced from the first wide surface 11 from upstream to downstream in the cooling water flow direction, and the protrusion portions 30 each are formed such that, in a cross section taken along the cooling water flow direction, a virtual first circle C1 is inscribed at three points on the first wide surface 11, the second inclined surface 32, and the first inclined surface 31 adjacent to the second inclined surface 32 downstream in the cooling water flow direction.

According to the configuration, the protrusion portions 30 each are formed such that, in the cross section taken along the cooling water flow direction, the virtual first circle C1 is inscribed at three points on the first wide surface 11, the second inclined surface 32, and the first inclined surface 31 adjacent to and downstream of the second inclined surface 32 in the cooling water flow direction. Therefore, when the cooling water flows from the first inclined surface 31 to the second inclined surface 32 adjacent to and downstream of the first inclined surface 31 in the cooling water flow direction, a longitudinal vortex is generated and flows along the second inclined surface 32, and a large longitudinal vortex is generated in a space in which the virtual first circle C1 is inscribed at the three points. Therefore, it is possible to improve heat exchange efficiency between the inverter module 8 and the cooling water in a space in which the virtual first circle C1 is inscribed at the three points. Therefore, the heat exchange efficiency between the inverter module 8 and the cooling water can be improved depending on how the cooling water flows through the flow path 20.

The protrusion portions 30 each include a peak portion 33 formed between the first inclined surface 31 and the second inclined surface 32 adjacent to the first inclined surface 31 downstream in the cooling water flow direction, and a valley portion 34 formed between the second inclined surface 32 and the first inclined surface 31 adjacent to the second inclined surface 32 downstream in the cooling water flow direction, and the protrusion portions 30 each is formed such that, in a cross section taken along the cooling water flow direction, a virtual second circle C2 is inscribed at three points on the first inclined surface 31 upstream of the peak portion 33, the second inclined surface 32 downstream of the peak portion 33, and a virtual facing surface S facing the first wide surface 11 and in which the valley portion 34 is located, and the peak portion 33 does not fall within the second circle C2.

According to the configuration, when the cooling water passes through the flow path 20 between the peak portion 33 and the first wide surface 11, the cooling water tends to flow in a direction nearly perpendicular to a ridge line of the peak portion 33 so as to reduce resistance. On the other hand, when the cooling water passes through the flow path 20 between the valley portion 34 and the first wide surface 11, the cooling water tends to flow in a direction along a ridge line of the valley portion 34 having low resistance. In this way, the cooling water alternately passes through the peak portion 33 and the valley portion 34, and thus a strong swirling flow (a longitudinal vortex) is generated in the valley portion 34 sandwiched between a pair of peak portions 33. Therefore, the longitudinal vortex can be efficiently generated.

Further, Rm1>Rm2, wherein a radius of the first circle C1 is Rm1 and a radius of the second circle C2 is Rm2.

According to the configuration, by setting Rm1>Rm2, it is possible to sufficiently secure a flow path cross-sectional area of the flow path 20 between the peak portion 33 and the first wide surface 11.

When P is a pitch between peak portions 33 adjacent to each other in the cooling water flow direction, and Dv is a distance between the peak portion 33 and the first wide surface 11, Rm1×P/Dv is 4 to 40.

According to the configuration, when Rm1×P/Dv is in a range of 4 to 40, performance of the cooling device 1 is improved as compared with a flat flow path in which the protrusion portions 30 are not formed. Therefore, by setting Rm1×P/Dv in the range of 4 to 40, a heat transfer coefficient can be improved, that is, a performance improvement margin can be increased.

The protrusion portions 30 adjacent to each other in the flow path width direction are inclined in opposite directions so as to alternate in the cooling water flow direction, ridge lines of the peak portions 33 adjacent to each other in the flow path width direction are continuously formed, and ridge lines of valley portions 34 adjacent to each other in the flow path width direction are continuously formed.

According to the configuration, it is possible to improve a temperature distribution of the cooling water in the flow path 20.

The protrusion portions 30 are formed over an entire width in the flow path width direction.

According to the configuration, when there is a portion where the protrusion portions 30 are not formed, the cooling water may bypass the portion, but the protrusion portions 30 are formed over the entire width in the flow path width direction, and thus it is possible to prevent a decrease in heat exchange efficiency.

The flow path 20 includes a central flow path 21 provided with the protrusion portions 30, a side flow path 22 provided outside the central flow path 21 in the flow path width direction, and a turn flow path 23 in which the cooling water is turned back from the central flow path 21 toward the side flow path 22.

According to the configuration, since the central portion of the inverter module 8 in the flow path width direction has a large heat generation amount, the inverter module 8 can be efficiently cooled by providing the protrusion portions 30 in the central flow path 21 that cools the central portion. The cooling water turned back via the turn flow path 23 flows through the side flow path 22, and thus it is possible to further cool a portion of the inverter module 8 having a relatively small heat generation amount.

The side flow path 22 is provided with the protrusion portions 30.

According to the configuration, since the protrusion portions 30 are formed not only in the central flow path 21 but also in the side flow path 22, the heat exchange efficiency of the inverter module 8 can be further improved.

The protrusion portions 30 may not be formed in the side flow path 22 depending on the heat generation amount of the inverter module 8. In this case, resistance of the cooling water can be reduced by not forming the protrusion portions 30 in the side flow path 22.

The flow path 20 is formed such that a downstream side in the cooling water flow direction is narrower in the flow path width direction than an upstream side in the cooling water flow direction.

According to the configuration, cooling water flowing through a narrow portion 27 has a higher flow velocity than cooling water flowing through a wide portion 25. Therefore, even when the inverter module 8 is cooled at the wide portion 25 and the width reducing portion 26 and the temperature of the cooling water is increased, the inverter module 8 can be cooled at the narrow portion 27 by increasing the flow velocity.

The first wide surface 11 is formed by a bottom surface of the inverter module 8.

According to the configuration, the heat exchange efficiency can be further improved by bringing the cooling water into direct contact with the inverter module 8.

The protrusion portions 30 each include: the peak portion 33 formed between the first inclined surface 31 and the second inclined surface 32 adjacent to the first inclined surface 31 downstream in the cooling water flow direction; the valley portion 34 formed between the second inclined surface 32 and the first inclined surface 31 adjacent to the second inclined surface 32 downstream in the cooling water flow direction; and a rectifying fin 37 extending downstream in the cooling water flow direction from a top portion 36 protruding downstream in the cooling water flow direction in a connection portion 35 between the peak portions 33 continuous in the flow path width direction.

According to the configuration, since the flow path 20 is partitioned in the flow path width direction by providing the rectifying fin 37, it is possible to prevent interference between longitudinal vortices of the cooling water on both sides of the rectifying fin 37. Therefore, it is possible to improve cooling performance while preventing an increase in resistance of the cooling water.

The first wide surface 11 extends linearly in one direction of the cooling water flow direction and a direction orthogonal to the cooling water flow direction, and extends linearly or is circularly curved in the other direction.

According to the configuration, not only in a case where the first wide surface 11 is formed in a planar shape, but also in a case where the flow path 20 is formed in the circumferential direction or in a case where the flow path 20 is circularly curved in the width direction, similarly, by providing the protrusion portions 30, the heat exchange efficiency between an electric motor 80 as the device to be cooled and the cooling water can be improved depending on how the cooling water flows through the flow path 20.

Although the embodiments of the present invention have been described above, the above-mentioned embodiments are merely a part of application examples of the present invention, and do not mean that the technical scope of the present invention is limited to the specific configurations of the above-mentioned embodiments.

For example, in the above embodiment, the cooling device 1 cools the inverter module 8 or the electric motor 80, but instead of these, the cooling device 1 may cool other devices to be cooled.

1. A cooling device that has a first wide surface and a second wide surface facing the first wide surface, and cools a device to be cooled with a fluid flowing through a flow path that is flat and formed between the first wide surface and the second wide surface, wherein
the second wide surface has a plurality of protrusion portions protruding into the flow path, the protrusion portions extending in a flow path width direction, the protrusion portions being arranged side by side in a fluid flow direction,
the first wide surface is not provided with the protrusion portions,
the protrusion portions each include:
a first inclined surface inclined to come close to the first wide surface from upstream to downstream in the fluid flow direction; and
a second inclined surface disposed alternately with the first inclined surface in the fluid flow direction and inclined to be distanced from the first wide surface from upstream to downstream in the fluid flow direction, and
the protrusion portions each are formed such that, in a cross section taken along the fluid flow direction, a virtual first circle is inscribed at three points on the first wide surface, the second inclined surface, and the first inclined surface adjacent to the second inclined surface downstream in the fluid flow direction.

2. The cooling device according to claim 1, wherein the protrusion portions each include:
a peak portion formed between the first inclined surface and the second inclined surface adjacent to the first inclined surface downstream in the fluid flow direction; and
a valley portion formed between the second inclined surface and the first inclined surface adjacent to the second inclined surface downstream in the fluid flow direction, and
the protrusion portions each is formed such that, in a cross section taken along the fluid flow direction, a virtual second circle is inscribed at three points on the first inclined surface upstream of the peak portion, the second inclined surface downstream of the peak portion, and a virtual facing surface facing the first wide surface and in which the valley portion is located, and the peak portion does not fall within the virtual second circle.

3. The cooling device according to claim 2, wherein Rm1>Rm2, where Rm1 is a radius of the virtual first circle and Rm2 is a radius of the virtual second circle.

4. The cooling device according to claim 3, wherein when P is a pitch between peak portions adjacent to each other in the fluid flow direction, and Dv is a distance between the peak portion and the first wide surface, Rm1×P/Dv is 4 to 40.

5. The cooling device according to claim 2, wherein
the protrusion portions adjacent to each other in the flow path width direction are inclined in opposite directions so as to alternate in the fluid flow direction,
ridge lines of peak portions adjacent to each other in the flow path width direction are continuously formed, and
ridge lines of valley portions adjacent to each other in the flow path width direction are continuously formed.

6. The cooling device according to claim 1, wherein the protrusion portions are formed over an entire width in the flow path width direction.

7. The cooling device according to claim 1, wherein the flow path includes:
a central flow path provided with the protrusion portions;
a side flow path provided outside the central flow path in the flow path width direction; and
a turn flow path in which the fluid is turned back from the central flow path toward the side flow path.

8. The cooling device according to claim 7, wherein the side flow path is provided with the protrusion portions.

9. The cooling device according to claim 1, wherein the flow path is formed such that a downstream side in the fluid flow direction is narrower in the flow path width direction than an upstream side in the fluid flow direction.

10. The cooling device according to claim 1, wherein the first wide surface is formed by a bottom surface of the device to be cooled.

11. The cooling device according to claim 1, wherein the protrusion portions each include:
a peak portion formed between the first inclined surface and the second inclined surface adjacent to the first inclined surface downstream in the fluid flow direction;
a valley portion formed between the second inclined surface and the first inclined surface adjacent to the second inclined surface downstream in the fluid flow direction; and
a rectifying fin extending downstream in the fluid flow direction from a top portion protruding downstream in the fluid flow direction in a connection portion between peak portions continuous in the flow path width direction.

12. The cooling device according to claim 1, wherein the first wide surface extends linearly in one direction of the fluid flow direction and a direction orthogonal to the fluid flow direction, and extends linearly or is circularly curved in another direction.
